(19) United States
(12) Patent Application Publication
(10) Pub. No.: US 2010/0027359 A1
(43) Pub. Date: Feb. 4, 2010

(54) Memory test circuit which tests address access time of clock synchronized memory

(75) Inventor: Akihiro Banno, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/461,066

(22) Filed: Jul. 30, 2009

(30) Foreign Application Priority Data
Aug. 4, 2008 (JP) 2008-200594

(51) Int. Cl. G11C 29/00; G11C 8/18; G11C 7/00

(52) U.S. Cl. 365/201; 365/233.1; 365/194

(57) ABSTRACT

A circuit for testing an access time of a clock synchronization type memory, includes a delay circuit, a sampling circuit and a coincidence detection circuit. The delay circuit generates a delayed clock obtained by delaying, by a time acceptable for a memory performance, a clock inputted to a memory. The sampling circuit takes in and outputs an output from the memory at the timing of the delayed clock. The coincidence detection circuit detects coincidence or non-coincidence by comparing the output from the sampling circuit with an expected value for the output from the memory.

### INCORPORATION BY REFERENCE

This application is based upon and claims the benefit of priority from Japanese Patent Application No. 2008-200594 which was filed on Aug. 4, 2008, the disclosure of which is incorporated herein in its entirety by reference.

### BACKGROUND OF THE INVENTION

1. Field of the Invention

The present invention relates to a memory test circuit, and more particularly, to a memory test circuit, a memory test device and a memory device for performing an evaluation test of an address access time of a memory.

2. Description of Related Art

An address access time is one of performance evaluation indicators for memories. In recent years, an increase in processing speed has been required along with an increase in memory capacity. Thus, a delay time acceptable for an address access time of a memory has become increasingly shorter, thereby making it more difficult to accurately evaluate address access times. Here, Patent Document 1 discloses a semiconductor integrated circuit device including a speed judgment circuit that makes an acceptance judgment as to whether or not an address access time of a memory is an acceptable time.

FIG. 7 is a diagram showing a configuration of a semiconductor integrated circuit disclosed in Patent Document 1. In FIG. 7, the semiconductor integrated circuit includes a memory circuit 100, a built-in self test (BIST) circuit 110 and a speed judgment circuit 120. Upon receipt of a test signal TIN, the BIST circuit 110 automatically generates an address signal AD, a write data signal DI, and a write/read control signal CNT, supplies the memory circuit 100 with those signals, and executes basic tests such as a marching test and a checkerboard test.

FIG. 8 is a diagram showing a configuration of the speed judgment circuit 120.

The speed judgment circuit 120 includes an AND circuit 130, a set-reset flip-flop circuit 131, a delay circuit 132, a flip-flop circuit 133, and an EX-NOR circuit 134.

FIG. 9 illustrates a timing chart for the operations of the speed judgment circuit 120.

When the memory circuit 100 is tested, an address signal AD is outputted from the BIST circuit 110, and is inputted to the memory circuit 100 and the AND circuit 130. Then, at a time t1, when the address signal AD exhibiting the maximum value of an address (that is, an address signal being entirely at the H level) is outputted from the BIST circuit 110, the AND circuit 130 outputs a signal CD at the H level. This signal CD is inputted to a clock terminal (C) of the flip-flop circuit 131. In response to the signal, the flip-flop circuit 131 takes in an H-level signal constantly inputted to a data terminal (D) thereof, and raises an output signal Q1 from the L level to the H level. The output signal Q1 of the flip-flop circuit 131 is branched into two, one of which is inputted to a reset terminal (R) of the flip-flop circuit 131 via the delay circuit 132. Since a rising signal of the flip-flop circuit 131 is inputted to the reset terminal (R) with a predetermined delay, the output signal Q1 from the flip-flop circuit 131 results in a one-shot pulse having a predetermined time width (TD). The other one of those into which the output signal Q1 from the flip-flop circuit 131 is branched is inputted to a clock terminal (C) of the flip-flop circuit 133 in the next stage. While an output DOUT from the memory circuit 100 is inputted to a data terminal (D) of the flip-flop circuit 133, the flip-flop circuit 133 takes in the output data DOUT from the memory circuit 100 at the timing when the clock (C) falls (that is, a timing t2 when Q1 falls), and outputs an output signal Q2. The output signal Q2 from the flip-flop circuit 133 is inputted to the EX-NOR circuit 134 in the next stage along with an expected value generated from the BIST circuit 110. In the EX-NOR circuit 134, the output signal Q2 from the flip-flop circuit 133 is checked with the expected value generated from the BIST circuit 110, and a judgment is made as to whether data coinciding with the expected value has been outputted from the memory circuit 100 within the predetermined delay time (TD). Thereby, an address access time of the memory circuit 100 is evaluated.

[Patent Document 1] Japanese Patent Application Laid Open No. 2001-266595 (FIG. 1. FIG. 3, FIG. 7, paragraphs (0022) to (0026))

### SUMMARY

In the speed judgment circuit 120 of Patent Document 1, there is a problem that only an access time of a fixed address can be evaluated because of its configuration in which the address signal AD is inputted to the AND circuit 130 to trigger the operation of the speed judgment circuit 120. On the assumption that the maximum delay of an access time occurs in the uppermost address space of a memory area in a memory, Patent Document 1 describes that an address access time of the entire memory can be ensured with the above configuration.

However, in each of semiconductor memory circuits undergoing further miniaturization in recent years, transistors are designed to be the smallest possible size, and therefore, performances of the transistors tend to vary widely. On that condition, simply ensuring an access time for a fixed address (for example, the uppermost address) is insufficient as evaluation of memory performance since it cannot be affirmed that an access time in the uppermost address space is the largest or that an access time for a certain specific address is the largest.

As to an exemplary aspect of the present invention, a memory test circuit tests an access time of a clock synchronization type memory. The memory test circuit includes a first delay circuit that generates a delayed clock obtained by delaying, by a time acceptable for a memory performance, a clock supplied to the memory, a second sampling circuit that takes in and outputs an output from the memory at a timing of the delayed clock from the delay circuit, and a coincidence detection circuit that detects coincidence or non-coincidence (match or mismatch) by comparing an output from the sampling circuit with an expected value for an output from the memory.

According to the exemplary aspect, a test can be performed, with respect to all of address spaces in a memory, by using the delayed clock signal, as to whether data outputted under clock synchronization is outputted within an acceptable delay time. As has been described above, a test coverage for a memory speed is not limited to a specific address, and therefore, memory performance evaluation can be performed more accurately than can be performed conventionally.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a diagram showing a configuration of a memory device 200 according to a first exemplary embodiment of the present invention;

FIG. 2 is a timing chart for explaining, in the first exemplary embodiment, operations of a speed judgment circuit 500;

FIG. 3 is a timing chart for explaining, in the first exemplary embodiment, operations of the speed judgment circuit 500 in a case where an address access time of a memory has exceeded an acceptable delay time;

FIG. 4 is a diagram showing a configuration of a second exemplary embodiment;

FIG. 5 is a timing chart for explaining operations of the second exemplary embodiment;

FIG. 6 is a diagram showing a configuration of a third exemplary embodiment;

FIG. 7 illustrates a semiconductor integrated circuit in description of a related art;

FIG. 8 illustrates a speed judgment circuit shown in FIG. 7; and

FIG. 9 illustrates a timing chart for explaining operations of the speed judgment circuit shown in FIG. 7.

### DETAILED DESCRIPTION OF THE EXEMPLARY EMBODIMENTS

### First Exemplary Embodiment

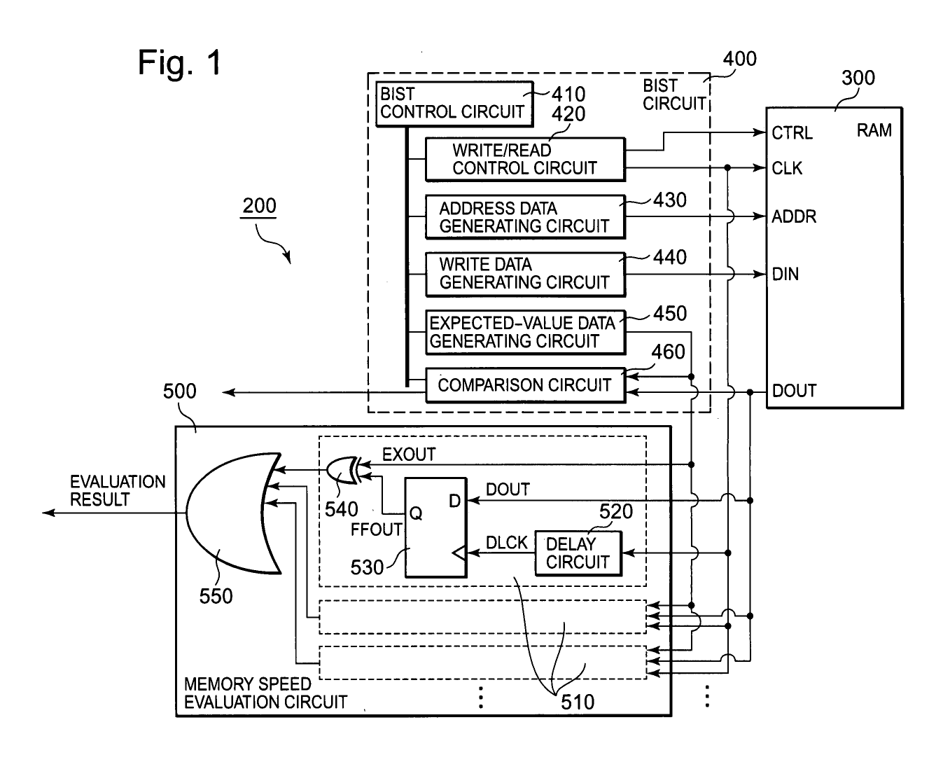

FIG. 1 is a diagram showing a configuration of a memory device 200 according to a first exemplary embodiment of the present invention. The memory device 200 includes a memory circuit (a memory) 300, a BIST circuit (a memory BIST circuit) 400 and a memory speed evaluation circuit (a memory test circuit) 500.

The memory circuit 300 is a clock synchronization type semiconductor memory. It is noted that a DRAM, an SRAM, a flash memory or the like can be employed as the memory circuit 300, and that a type thereof is not particularly limited.

The BIST circuit 400 is a general BIST circuit for a memory test. Specifically, the BIST circuit includes a BIST control circuit 410, a write/read control circuit 420, an address data generating circuit 430, a write data generating circuit 440, an expected-value data generating circuit 450 and a comparison circuit 460.

The address data generating circuit 430 automatically generates address data in sequence, and inputs these address data to an address input terminal ADDR of the memory circuit 300. The write data generating circuit 440 generates test data, and inputs the test data to a data input terminal DIN of the memory circuit 300. Thereby, the test data is sequentially written into a predetermined address space. Then, the memory circuit 300 is set into a read-out state by the write/read control circuit 420, and the data is read out from the memory circuit 300 in the order in which the addresses are seriated. At this time, the expected-value data generating circuit 450 generates expected-value data on the basis of test data that should be read out from the memory circuit 300, and outputs the expected-value data to the comparison circuit 460.

Output data is sequentially outputted from the memory circuit 300 in accordance with the clock timing, and the output data from the memory circuit 300 is checked with expected-value data (expected values for outputs) EXOUT by the comparison circuit 460. If the output data DOUT and the expected-value data EXOUT coincide with each other, then it is judged that data write/read has been accurately executed.

Next, the memory speed evaluation circuit 500 will be described.

The memory speed evaluation circuit 500 includes multiple judgment circuits 510 each provided as a sub-module that, in response to a fact that the output data DOUT from the memory circuit 300 is parallel data, judges a memory output speed by data bit.

Configurations of all of the judgment circuits 510 are basically the same. Each of the judgment circuits 510 includes a delay circuit 520, a flip-flop circuit (a sampling circuit) 530, and an XOR circuit (a coincidence detection circuit) 540.

A clock signal CLK inputted to the memory circuit 300 is branched and inputted to the delay circuit 520, and the delay circuit 520 outputs a delayed clock DLCK in which the clock signal CLK is delayed by a predetermined time. The maximum delay time acceptable as an address access time T_{AC} of the memory circuit 300 or less is set as the time TD by which the clock signal CLK is delayed. Although the delay circuit 520 can be realized by a configuration in which multiple stages of basic primitive gates, such as inverters, are stacked, a specific configuration thereof is not necessarily limited as long as a delay time can be controlled with the configuration.

To the flip-flop circuit 530, the delayed clock DLCLK from the delay circuit 520 is inputted through a clock terminal thereof, and the output data DOUT from the memory circuit 300 is inputted through a data terminal (D) thereof.

Thereby, the flip-flop circuit 530 takes in the output data DOUT from the memory circuit 300 at the timing of the delayed clock DLCK, and outputs sampling data FFOUT. If the output from the memory circuit 300 reaches the flip-flop circuit 530 earlier than the delay time TD of the delay circuit 520, then the output data FFOUT from the flip-flop circuit 530 coincides with the output data DOUT from the memory circuit 300. On the other hand, if the output data DOUT from the memory circuit 300 is delayed more than the acceptable value, then the flip-flop circuit 530 cannot take in the output data DOUT from the memory circuit 300.

The expected-value data EXOUT from the expected-value data generating circuit 450 and the sampling data FFOUT from the flip-flop circuit 530 are inputted to the XOR circuit 540, and the XOR circuit 540 outputs a judgment signal OROUT in accordance with coincidence or non-coincidence therebetween.

Thereby,_coincidence or non-coincidence between the expected-value data EXOUT and the sampling data FFOUT is judged. If the expected-value data EXOUT and the sampling data FFOUT coincide with each other, then the judgment signal OROUT at the L level is outputted. On the other hand, if the expected-value data EXOUT and the sampling data FFOUT do not coincide with each other, then the judgment signal OROUT at the H level is outputted.

Additionally, the memory speed evaluation circuit 500 includes an OR circuit (a second coincidence detection circuit) 550.that receives, as input signals, the judgment signals OROUT from all of the judgment circuits 510. The OR circuit 550 outputs a signal at the L level as an evaluation result when outputs from all of the judgment circuit 510 are at the L level.

In this case, it indicates that the expected-value data EXOUT and the sampling data FFOUT have coincided with each other in each of all of the judgment circuits 510, and it is therefore found that all of data bits in designated addresses are correctly outputted within the acceptable delay time. On the other hand, when any one of data bits outputted in parallel with each other is delayed more than the acceptable delay time, an output from the OR circuit 550 is at the H level, and thus an abnormality is detected.

Next, operations of the memory speed evaluation circuit 500 will be described.

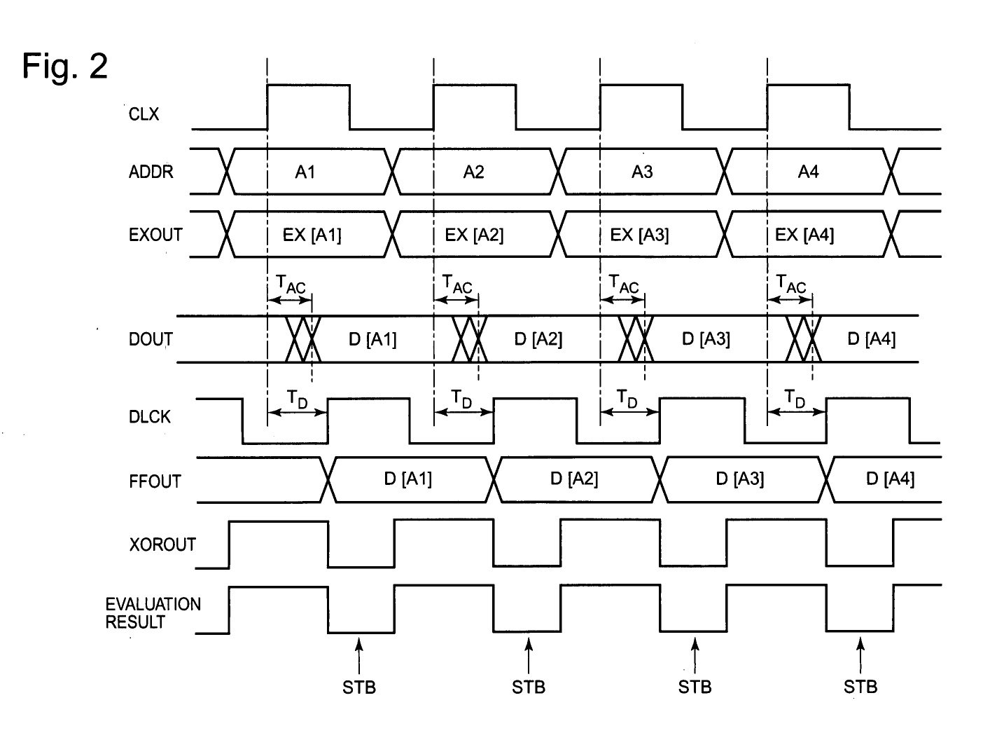

FIG. 2 is a timing chart for explaining operations of the memory speed evaluation circuit 500.

Read mode is set. The address data generating circuit 430 generates address data and inputs the address data to the address terminal ADDR of the memory circuit. At the same time, the expected-value data generating circuit 450 generates, from the address data, expected-value data that should be outputted, and outputs the expected-value data to the XOR circuit 540. The memory circuit 300 takes in the address data ADDR at the timing of the clock CLK, accesses an address space, and outputs the data DOUT. At this time, the address access time T_{AC} of the memory circuit 300 causes a delay time until the data is outputted. The memory output data DOUT is inputted to the data terminal (D) of the flip-flop circuit 530. The clock CLK is inputted also to the delay circuit 520, and the delay circuit 520 generates the delayed clock DLCK delayed by the acceptable delay time TD.

The delayed clock DLCK is inputted to the clock terminal (D) of the flip-flop circuit 530. Then, in the flip-flop circuit 530, data having been inputted to the data terminal of the flip-flop circuit 530 are sampled at the timing of the delayed clock DLCLK.

In FIG. 2, since the memory output data DOUT is outputted at a timing earlier than the delayed clock DLCK, the flip-flop circuit 530 takes in and outputs the memory output data DOUT at the timing of the delayed clock.

The output data FFOUT from the flip-flop circuit 530 is outputted to the XOR circuit 540. While the expected-value data EXOUT generated by the expected-value data generating circuit 450 is inputted to another input terminal of the XOR circuit 540, the XOR circuit 540 checks the expected-value data EXOUT with FFOUT. If they coincide with each other, then the XOR circuit 540 outputs a judgment result XOROUT at the L level. Then, if all of the judgment results XOROUT of the multiple judgment circuits 510 provided corresponding to parallel data outputted by the memory coincide with one another at the L level, then a judgment result at the L level is outputted from the OR circuit 550, whereby it is found that all of data bits in designated addresses have been correctly outputted within the acceptable delay time.

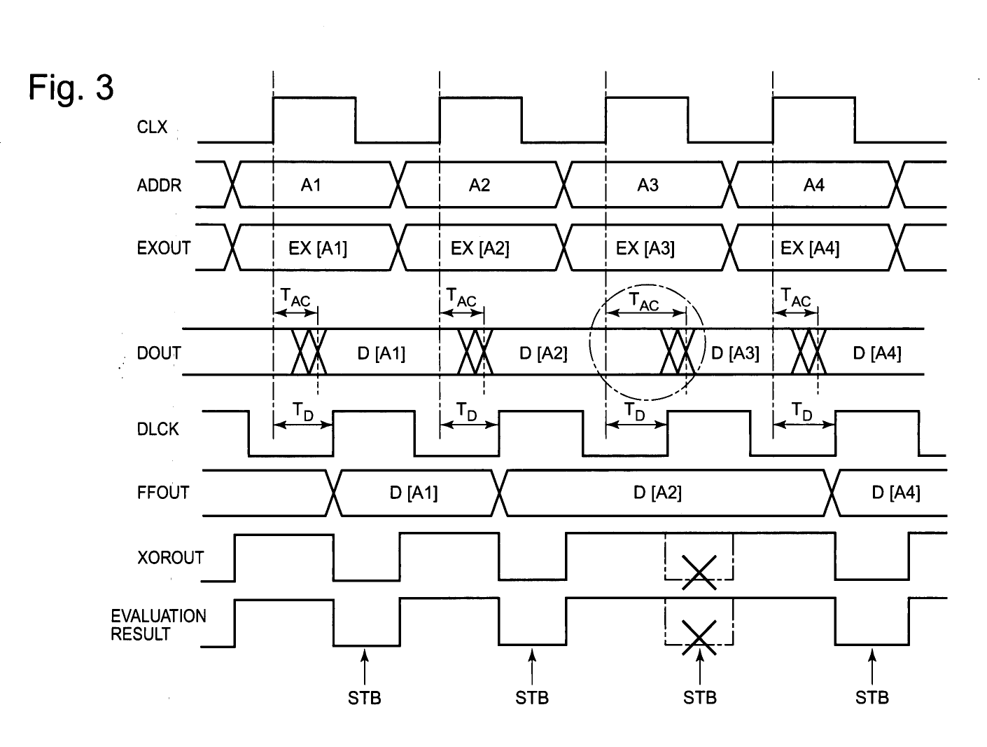

Next, detection in a case where an abnormal operation has occurred will be described with reference to FIG. 3.

FIG. 3 is a timing chart in a case where the address access time T_{AC} of an address A3 has exceeded the acceptable delay time. FIG. 3 shows a case where, while the memory output data DOUT are sequentially outputted from the memory circuit 300 on the basis of designation of the address ADDR and a clock signal, output data D[A3] has exceeded the acceptable delay time T_{D}.

The flip-flop circuit 530 takes in data through the data terminal (D) at the timing of the delayed clock DLCLK but cannot take in the output data D[A3] from the memory circuit 300 since the output data D[A3] has not yet reached the terminal. For this reason, the output FFOUT from the flip-flop circuit 530 turns out to be different from the output data D[A3]. In this case, the XOR circuit 540 outputs a signal at the H level as the judgment result XOROUT since the expected-value data EXOUT, which is one input thereto, and the output FFOUT from the flip-flop circuit 530, which is the other input thereto, are different in value from each other. In the OR circuit 550, if any one of the judgment results from the judgment circuits 510 is abnormal (at the H level), then the judgment result from the OR circuit 550 is at the H level. Thereby, a state having at least 1 bit, out of the output data in the designated addresses ADDR, delayed more than the acceptable time is detected.

As has been described above, according to the exemplary embodiment, an output speed of the clock synchronization type memory 300 can be evaluated. At this time, since data output speeds can be compared with the acceptable delay time for all of the address spaces of the memory 300, extremely accurate evaluation can be performed as compared to a case where a memory performance is evaluated only with an output speed of a specific address, as described in Patent Document 1.

### Second Exemplary Embodiment

Next, a second exemplary embodiment of the present invention will be described.

A basic configuration of the second exemplary embodiment is, the same as that of the first exemplary embodiment, but is characterized in that detection of a judgment result is facilitated by provision of a flip-flop circuit 620 in a stage following the OR circuit 550.

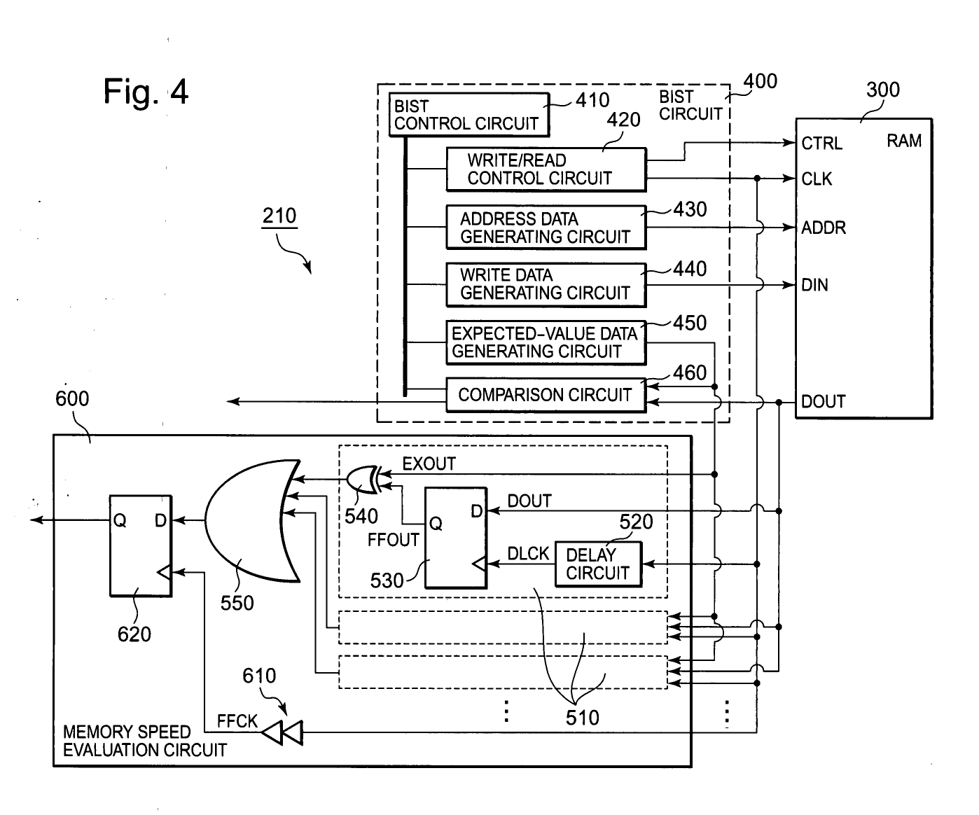

FIG. 4 is a diagram showing a configuration of the second exemplary embodiment.

In FIG. 4, a memory speed evaluation circuit 600 includes a detection-purpose delayed clock generating circuit (a second delay circuit) 610, and an evaluation-result sampling circuit (a second sampling circuit) 620.

The detection-purpose delayed clock generating circuit 610 is a circuit that generates a delayed clock delayed to a slightly greater extent than the delay circuit 520. The same clock signal CLK as one inputted to the memory circuit 300 and the delay circuit 520 is inputted to the detection-purpose delayed clock generating circuit 610, and the delayed clock having been delayed is outputted as a clock FFCK of the evaluation-result sampling circuit. The evaluation-result sampling circuit 620 is formed of a flip-flop circuit. The clock FFCK is inputted to a clock terminal of the evaluation-result sampling circuit 620, and the evaluation result OROUT from the OR circuit 550 is inputted to a data terminal (D). The evaluation-result sampling circuit 620 takes in and outputs, as a detection result, the evaluation result OROUT at the timing of the clock FFCK.

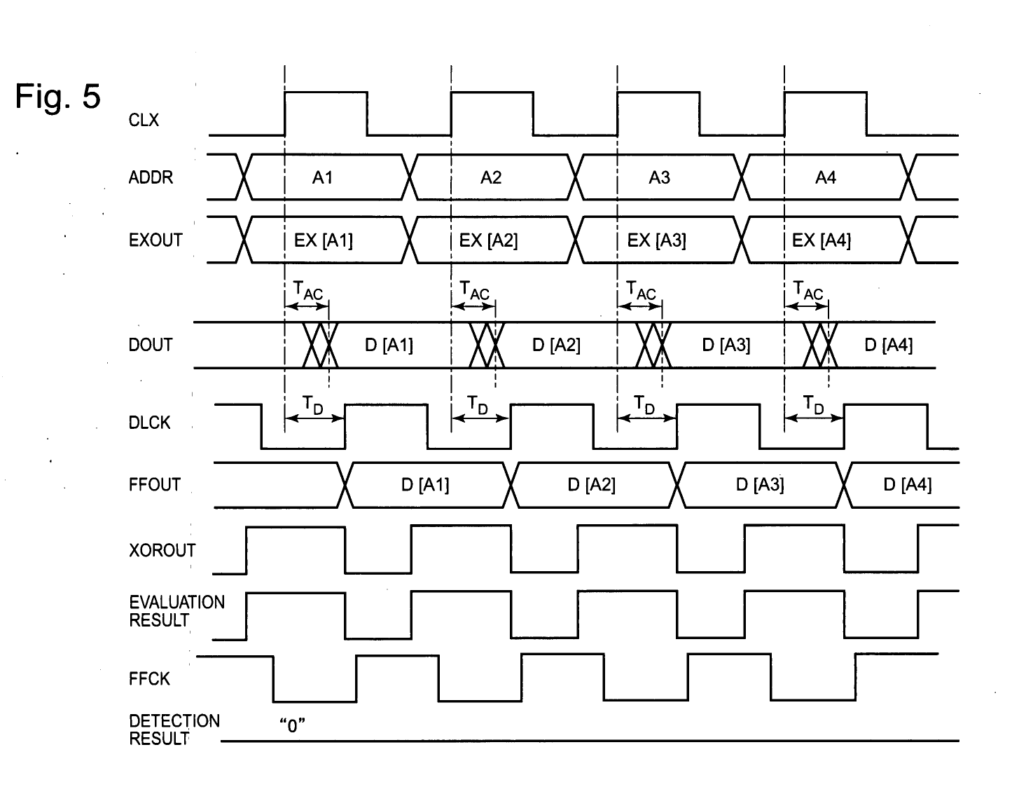

FIG. 5 is a timing chart for explaining operations of the second exemplary embodiment.

In FIG. 5, the judgment result OROUT has been outputted from the OR circuit 550. Additionally, the detection-purpose delayed clock generating circuit 610 outputs the clock FFCK having the clock signal delayed, and the evaluation-result sampling circuit 620 takes in the judgment result OROUT at the timing of the clock FFCK.

Thereby, the evaluation-result sampling circuit 620 can take in the judgment result OROUT in a timely fashion just when the judgment result OROUT falls to the L level. Then, if the judgment result taken in by the evaluation-result sampling circuit 620 is at the L level indicating normal operation of the memory circuit, then the detection result outputted from the evaluation-result sampling circuit 620 is constantly at the L level. Additionally, when there is a rise in the evaluation result OROUT with a delay in output speed of the memory circuit, the evaluation-result sampling circuit 620 takes in and outputs this, thereby detecting an abnormality.

As has been described above, according to the second exemplary embodiment, the evaluation-result sampling circuit 620 can sample the judgment result OROUT automatically and in a timely fashion, and therefore, can easily detect normal operation or abnormal operation of the memory.

Consequently, evaluation of a memory speed can be accurately performed even in a case where the judgment result OROUT changes at a high speed when a memory test is performed at a high speed.

### Third Exemplary Embodiment

Next, a third exemplary embodiment of the present invention will be described.

The third exemplary embodiment is characterized in that plural memory units 310 share the memory speed evaluation circuit 500.

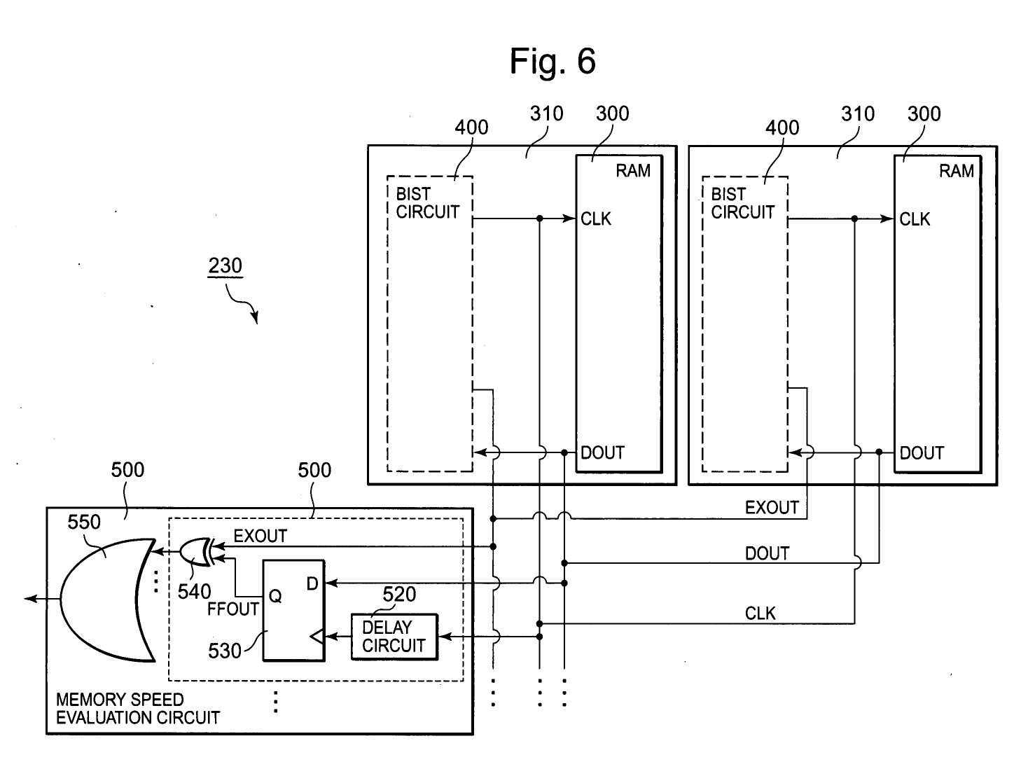

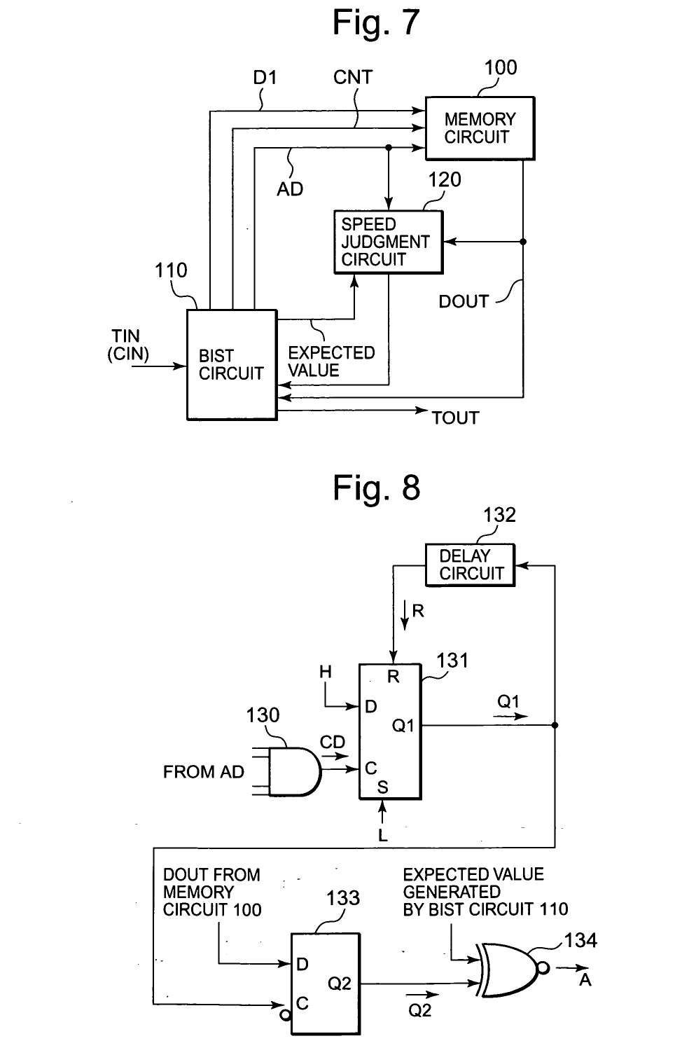

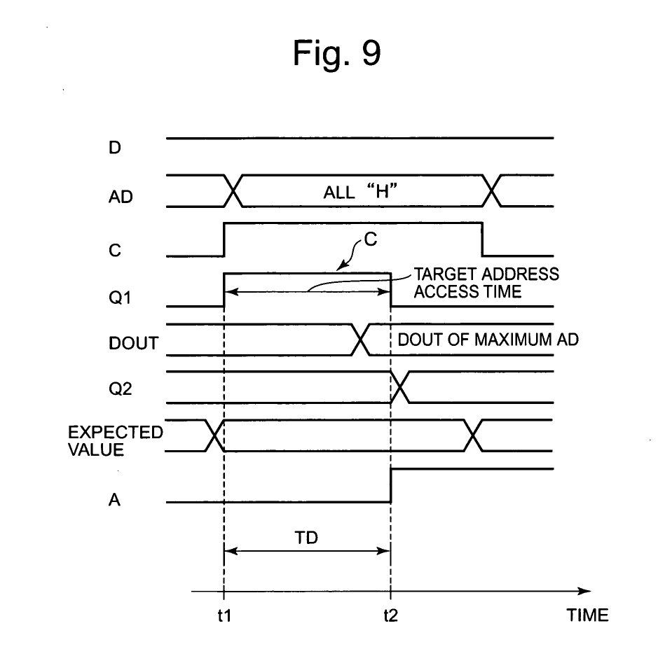

FIG. 6 is a diagram showing a configuration of a memory device 230 according to the third exemplary embodiment.

In FIG. 6, a configuration of the memory speed judgment circuit 500 is the same as the configuration thereof described in the first exemplary embodiment. Additionally, in the third exemplary embodiment, two memory units 310 each formed of the memory circuit 300 and the BIST circuit 400 are provided, and the two memory units 310 are connected to the memory speed evaluation circuit 500. With the configuration as described above, a memory output speed is evaluated by the memory speed evaluation circuit for each of the memory units 310.

According to the third exemplary embodiment as described above, the plural memory units 310 share the memory speed evaluation circuit 500. Thereby, even in a case where plural memory units are provided so that a memory capacity may be increased, operation speeds of all of the memory units can be ensured while a circuit configuration can be simplified.

Note that, needless to say, even in a case where plural (three or more) memory units are provided, the speed judgment circuit can be shared thereby in the same manner as in this exemplary embodiment.

Cases where output data is outputted in parallel from a memory circuit have been taken as examples. However, in a case where data is outputted from the memory circuit as a serial signal, it is obvious that the memory speed judgment circuit needs only to include one judgment circuit so as to correspond to the serial signal.

It is obvious that, when being specifically configured, the memory test circuit, memory test device and memory device according to the present invention can be configured of semiconductor integrated circuits.

Further, it is noted that Applicant's intent is to encompass equivalents of all claim elements, even if amended later during prosecution.

What is claimed is:

1. A memory test circuit for testing an access time of a clock synchronization type memory, comprising:
a delay circuit that generates a delayed clock obtained by delaying, by a time acceptable for a memory performance, a clock supplied to the memory;
a sampling circuit that takes in and outputs an output from the memory at a timing of the delayed clock from the delay circuit; and
a coincidence detection circuit that detects coincidence or non-coincidence by comparing an output from the sampling circuit with an expected value for the output from the memory.

2. The memory test circuit according to claim 1, wherein the delay circuit includes a plurality of primitive gates.

3. The memory test circuit according to claim 1,
wherein the delay circuit and the sampling circuit comprises a first delay circuit and a first sampling circuit, respectively, the memory test circuit further comprising:
a second delay circuit that delays the clock to a greater extent than a delay of the first delay circuit; and
a second sampling circuit that takes in and outputs an output from the coincidence detection circuit at a timing of a delayed clock from the second delay circuit.

4. The memory test circuit according to claim 1, wherein:
the memory is capable of outputting parallel data; and
the sampling circuit and the coincidence detection circuit are provided in parallel by a number of bits outputted from the memory.

5. The memory test circuit according to claim 4,
wherein the coincidence detection circuit, the delay circuit, and the sampling circuit comprises a first coincidence detection circuit, a first delay circuit, and a first sampling circuit, respectively, the memory test circuit further comprising:
a second coincidence detection circuit that receives an output from the first coincidence detection circuit;
a second delay circuit that delays the clock to a greater extent than a delay of the first delay circuit; and
a second sampling circuit that takes in and outputs an output from the second coincidence detection circuit at a timing of a delayed clock from the second delay circuit.

6. A memory test device, comprising:
the memory test circuit according to claim 1; and
a memory BIST circuit that writes and reads test data into and out of the memory, and executes a memory test for comparing an output and the expected value for the output from the memory.

7. A memory device, comprising:
the memory test device according to claim 6; and
a memory.

8. The memory device according to claim 7, further comprising a plurality of memories including the memory, wherein
the memory test circuit is shared by the plurality of memories.

9. A memory test unit, comprising:
a built-in self test (BIST) circuit that provides an address data, an expected value and a clock signal, the address data and the clock signal being supplied to a clock synchronized memory; and
a memory speed evaluation circuit comprising:
a delay circuit which delays the clock signal to produce a delayed clock signal;
a latch circuit which latches an output from the memory based on the delayed clock signal; and
a coincidence circuit which compares an output of the latch circuit with the expected value.

10. The memory test unit as claimed in claim 9, further comprising:
a delay generator which delays the clock signal with a delay period larger than a delay period when the delay circuit delays the clock signal, in order to produce a second delayed clock signal; and
a sampling circuit which latches an output of the coincidence circuit based on the second delayed clock signal.

11. The memory test unit as claimed in claim 9, wherein the memory speed evaluation circuit is shared by a first pair of the BIST circuit and the memory and a second pair of the BIST circuit and the memory.

12. A method of evaluating a memory speed, comprising;
delaying a clock signal produced in a BIST circuit to produce a delayed clock signal;
latching an output from a clock synchronized memory in response to the delayed clock signal; and
determining whether a latch output and an expected value are coincident.
